(19) United States
(12) Patent Application Publication
(10) Pub. No.: US 2002/0006704 A1
(43) Pub. Date: Jan. 17, 2002

(54) Process for forming gate oxide layer

(75) Inventors: Mao-Song Tseng, Science-Based Industrial Park (TW); Su-Wen Chang, Science-Based Industrial Park (TW); Chien-Ping Chang, Science-Based Industrial Park (TW); Chiao-Shun Chuang, Science-Based Industrial Park (TW)

Correspondence Address: NIKOLAI MERSEREAU & DIETZ, P.A., 820 INTERNATIONAL CENTRE, 900 SECOND AVENUE SOUTH, MINNEAPOLIS, MN, 55402

(73) Assignee: Mosel Vitelic Inc., Science-Based Industrial Park (TW)

(21) Appl. No.: 09/759,436

(22) Filed: Jan. 12, 2001

(30) Foreign Application Priority Data
Jul. 17, 2000 (TW) 89114279

(51) Int. Cl. H01L 21/8234

(52) U.S. Cl. 438/270

(57) ABSTRACT

A process for forming a gate oxide layer of a trench power MOSFET is provided. The process includes steps of providing a silicon substrate, forming a mask layer on the silicon substrate, removing a portion of the mask layer to expose a portion of the silicon substrate, removing the exposed portion of the silicon substrate to form the trench, removing remaining portion of the mask layer, forming a sacrificial oxide layer on the silicon substrate and on the bottom and sidewall of the trench by thermal oxidation under an operating temperature ranged from 1150 to 1300° C. and an operating time ranged from 20 to 60 minutes, removing the sacrificial oxide layer, and forming a gate oxide layer on the silicon substrate and on the bottom and sidewall of the trench.

### FIELD OF THE INVENTION

The present invention is related to a process for forming a gate oxide layer, and more particularly to a process for forming a gate oxide layer applied in manufacturing a trench power MOSFET.

### BACKGROUND OF THE INVENTION

It's well known that forming a gate oxide is one of the most important steps for manufacturing a semiconductor device. The quality of a gate oxide layer is related to the yield of a semiconductor device, such as a trench power MOSFET.

First of all, please refer to FIGS. 1(a)˜(f) schematically showing a method for forming a gate oxide layer 15 according to the prior art. This method is described in detail as follows.

As shown in FIG. 1(a), a mask layer 11 is formd on a silicon substrate 10 by chemical vapor deposition (CVD).

In FIG. 1(b), a portion of the mask layer 11 is removed by photolithography and a dry etching step to expose a portion of the silicon substrate 10.

In FIG. 1(c), the exposed portion of the silicon substrate 10 is removed by a dry etching step to form a trench 12.

In FIG. 1(d), the remained portion of the mask layer 11 is then removed by a wet etching step to expose the surface of the silicon substrate 10 and the trench 12. Thereafter, a dry etching step, i.e. soft etching step, is performed for rounding the top corner 131 and the bottom corner 132 of the trench 12. It's well known that the objective of rounding the top corner 131 and the bottom corner 132 is used for preventing leakage current of the gate oxide layer resulted from the electrical discharge by the top corner 131 and the bottom corner 132 of the trench 12. On the other hand, rounding the top corner 131 and the bottom corner 132 can also prevent the breakdown voltage of a gate from being lowered.

In FIG. 1(e), for recovering the damaged silicon substrate 10 and further rounding the top corner 131 and the bottom corner 132 of the trench 12, a sacrificial oxide layer 14 having a thickness of about 1000 Åis formed on the silicon substrate 10 by thermal oxidation under an operating temperature of about 1000° C. and an operating time of about 30 minutes.

In FIG. 1(f), the sacrificial oxide layer 14 is removed to expose the surface of the silicon substrate 10 and the trench 12 by a wet etching step, and then a gate oxide layer 15 is formed on the silicon substrate 10 and on the bottom and sidewall of the trench 12.

However, the conventional method for forming a gate oxide layer has some disadvantages described as follows.

1. As shown in FIG. 1(d), in spite of that a soft etching step is performed for rounding the top corner 131 and the bottom corner 132 of the trench 12, the soft etching step might result in damaging the surface structure of the silicon substrate 10. Therefore, the leakage current might be increased and the breakdown voltage of the gate might be lowered due to the damaged surface structure of the silicon substrate 10. If the soft etching step could be skipped, the process for forming the gate oxide layer 15 would be expectably simplified and the quality of the gate oxide layer 15 would be raised.

2. As shown in FIG. 1(e), for recovering the damaged silicon substrate 10 and further rounding the top corner 131 and the bottom corner 132 of the trench 12, a sacrificial oxide layer 14 is formed on the silicon substrate 10 by thermal oxidation. However, according to the conventional thermal oxidation for forming a sacrificial oxide layer 14, the operating temperature is not high enough and the operating time is so short that the thickness of the formed sacrificial oxide layer 14 is too thin to completely recover the damaged silicon substrate 10. In addition, the top corner 131 and the bottom corner 132 of the trench 12 can't be completely rounded owing to low temperature of thermal oxidation. Therefore, electrical discharge by the top corner 131 and the bottom corner 132 might still easily arise, and thus contribute to increase the leakage current of the gate oxide layer 15. Certainly, the breakdown voltage of the gate might also be lowered.

Accordingly, it is attempted by the present applicant to solve the above-described problems encountered in the prior arts.

### SUMMARY OF THE INVENTION

An object of the present invention is to provide a process of forming a gate oxide layer with high quality.

Another object of the present invention is to provide a process of forming a gate oxide layer for lowing leakage current of the gate oxide layer.

A further object of the present invention is to provide a process of forming a gate oxide layer for raising the breakdown voltage of the gate.

According to one aspect of the present invention, a process for forming a gate oxide layer of a trench power MOSFET is provided. The process comprises steps of (a) providing a silicon substrate having a trench therein, (b) forming a sacrificial oxide layer on the silicon substrate and on the bottom and sidewall of the trench by thermal oxidation under an operating temperature ranged from 1150 to 1300° C. and an operating time ranging from 20 to 60 minutes, (c) removing the sacrificial oxide layer, and (d) forming a gate oxide layer under an operating temperature ranged from 1000 to 1200° C. on the silicon substrate and on the bottom and sidewall of the trench.

Preferably, the step (a) comprises steps of (a1) providing the silicon substrate, (a2) forming a mask layer on the silicon substrate, (a3) removing a portion of the mask layer to expose a portion of the silicon substrate, (a4) removing the exposed portion of the silicon substrate to form the trench, and (a5) removing remaining portion of the mask layer.

Preferably, the mask layer is a silicon oxide layer.

Preferably, the mask layer is a silicon nitride layer.

Preferably, the mask layer is formed by chemical vapor deposition (CVD).

Preferably, the step (a3) is performed by photolithography and a dry etching step.

Preferably, the step (a4) is performed by a dry etching step.

Preferably, the step (a5) is performed by a wet etching step.

Preferably, the step (c) is performed by a wet etching step.

Preferably, the step (d) is performed by thermal oxidation.

Preferably, the sacrificial oxide layer has a thickness ranging from 1100 to 1500 Å.

According to another aspect of the present invention, a process for forming a gate oxide layer of a trench power MOSFET is provided. The process comprises steps of (a) providing a silicon substrate, (b) forming a mask layer on the silicon substrate, (c) removing a portion of the mask layer to expose a portion of the silicon substrate, (d) removing the exposed portion of the silicon substrate by plasma etch to form the trench, (e) removing remaining portion of the mask layer, (f) forming a sacrificial oxide layer on the silicon substrate and on the bottom and sidewall of the trench by thermal oxidation under an operating temperature ranged from 1150 to 1300° C. and an operating time ranged from 20 to 60 minutes, (g) removing the sacrificial oxide layer, and (h) forming a gate oxide layer on the silicon substrate and on the bottom and sidewall of the trench.

Preferably, the mask layer is a silicon oxide layer.

Preferably, the mask layer is a silicon nitride layer.

Preferably, the sacrificial oxide layer has a thickness ranged from 1100 to 1500 Å.

### BRIEF DESCRIPTION OF THE DRAWING

The present invention may best be understood through the following description with reference to the accompanying drawings, in which:

FIGS. 1(a)˜(f) illustrate a conventional method for forming a gate oxide layer according to the prior art;

FIGS. 2(a)˜(e) illustrate a method for forming a gate oxide layer according to the present invention; and

FIG. 3 is a plot showing the dependence of gate oxide leakage current on gate voltage for a gate formed by the conventional method and the present invention.

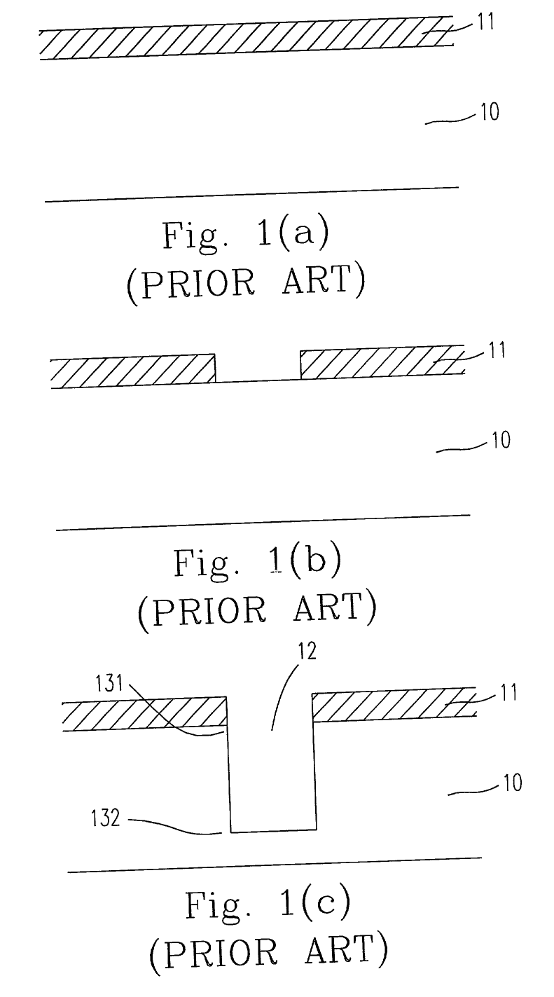

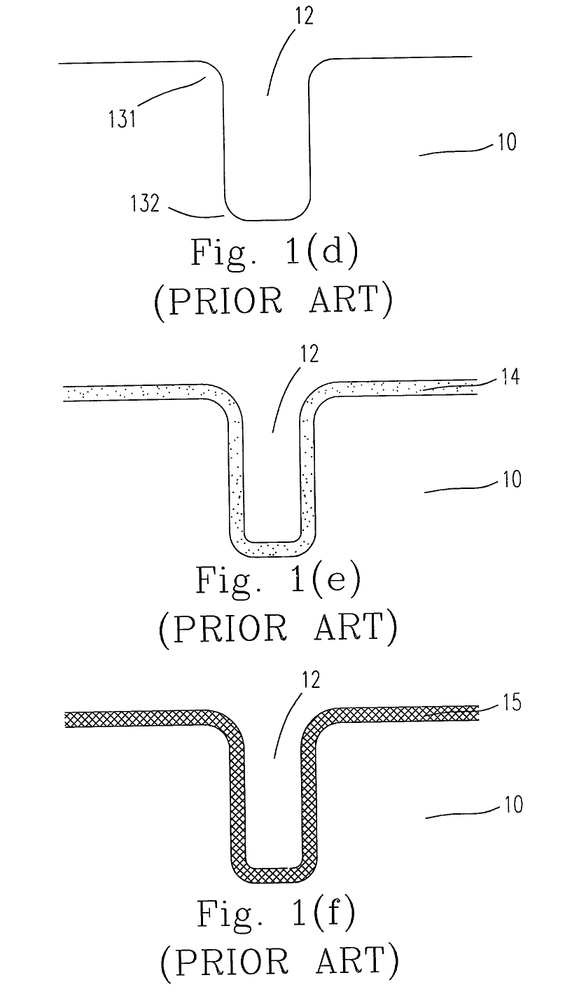

### DETAILED DESCRIPTION OF THE PREFERRED EMBODIMENTS

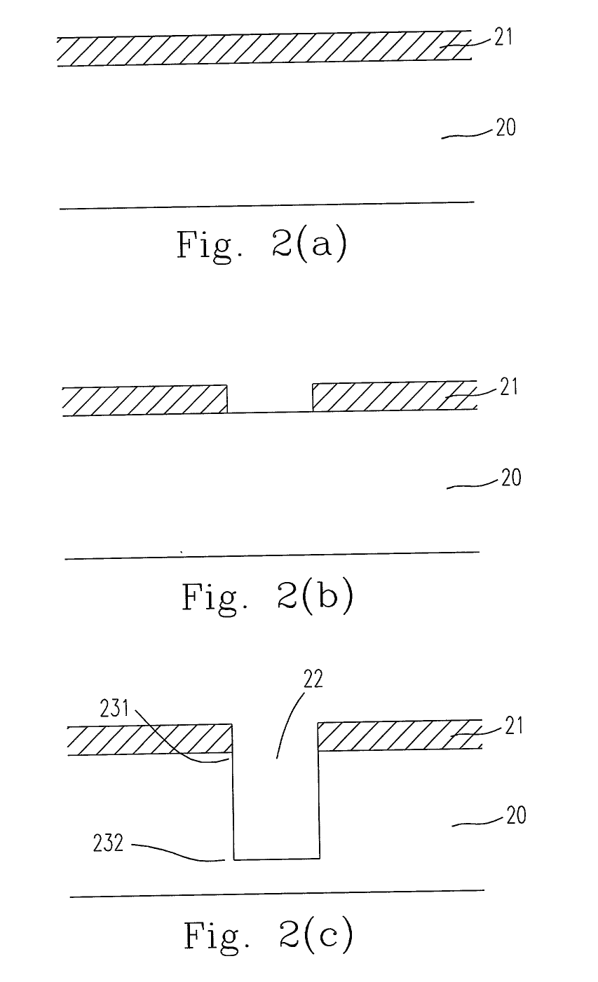

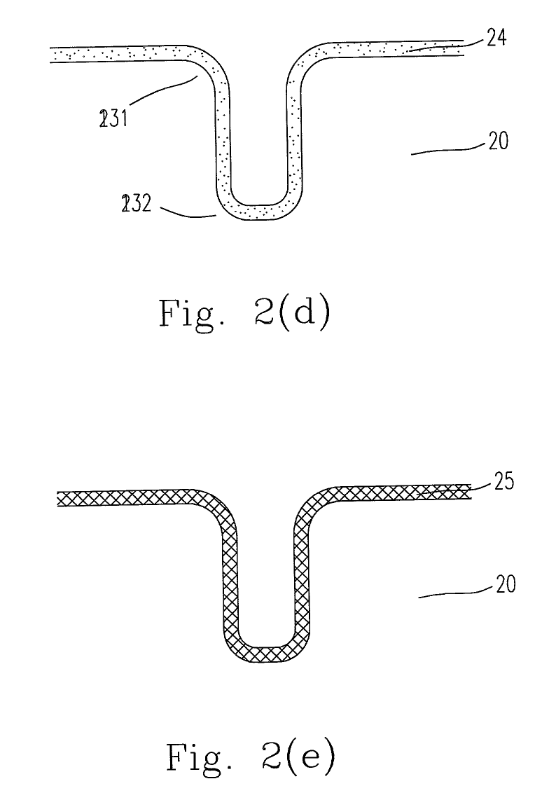

The present invention can be better understood by referring to FIG. 2(a)˜(e) schematically showing a method for forming a gate oxide layer 25 according to the present invention.

As shown in FIG. 2(a), a mask layer 21 is formed on a silicon substrate 20 by chemical vapor deposition (CVD). Preferably, the mask layer 11 is a silicon oxide layer or a silicon nitride layer.

In FIG. 2(b), a portion of the mask layer 21 is removed by photolithography and a dry etching step to expose a portion of the silicon substrate 20.

In FIG. 2(c), the exposed portion of the silicon substrate 20 is removed by a dry etching step to form a trench 22.

In FIG. 2(d), for recovering the damaged silicon substrate 20 and rounding the top corner 231 and the bottom corner 232 of the trench 22, a sacrificial oxide layer 24 having a thickness ranged from 1100 to 1500 Å is formed on the silicon substrate 20 by thermal oxidation under an operating temperature ranged from 1150 to 1300° C. and an operating time ranged from 20 to 60 minutes.

In FIG. 2(e), the sacrificial oxide layer 24 is removed to expose the surface of the silicon substrate 20 and the trench 22 by a wet etching step, and then a gate oxide layer 25 is formed on the silicon substrate 10 under an operating temperature ranged from 1000 to 1200° C. and on the bottom and sidewall of the trench 22.

According to the present invention, a soft etching step can be skipped. Therefore, the process for forming the gate oxide layer 25 is simplified and the quality of the gate oxide layer 25 is raised. In addition, as shown in FIG. 2(d) for forming a sacrificial oxide layer 24 by thermal oxidation, the thickness of the sacrificial oxide layer 24 is increased by raising the operating temperature and extending the operating time of the thermal oxidation. The damaged silicon substrate 20 can be completely recovered, and the top corner 231 and the bottom corner 232 of the trench 22 can also be completely rounded. It is obvious that the problems of the leakage current and the decreased breakdown voltage of the gate encountered in the prior arts can be solved.

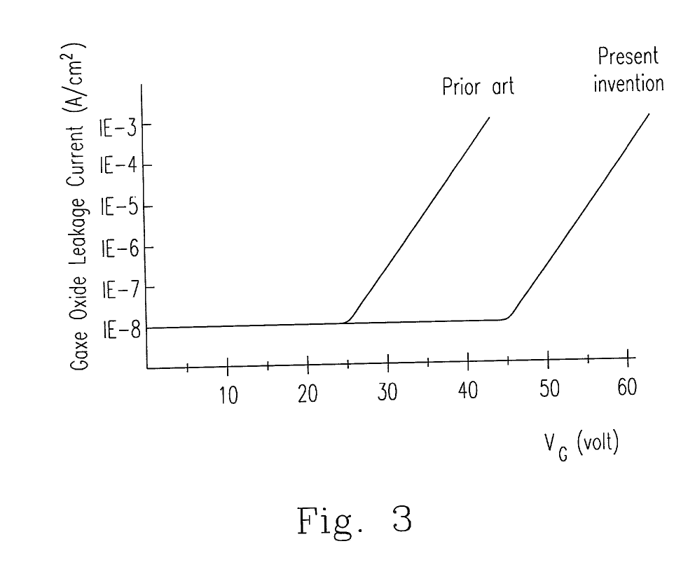

Please refer to FIG. 3 showing the comparison of the breakdown voltage (V_{G}) of a gate having a thickness of 700 Å between the prior art and the present invention. The breakdown voltage of a gate is about 25 volt according to the conventional method of forming a gate oxide layer, while which is about 45 volt according to the method of forming a gate oxide layer in the present disclosure. Obviously, the quality of the gate oxide layer is raised.

The present invention is directed to a process for forming a gate oxide layer applied in manufacturing a trench power MOSFET. According to the present invention, the problems encountered in the prior arts are solved. The present invention possesses inventive step, and it's unobvious for one skilled in the art to develop the present invention.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A process for forming a gate oxide layer of a trench power MOSFET, comprising steps of:
(a) providing a silicon substrate having a trench therein;
(b) forming a sacrificial oxide layer on said silicon substrate and on the bottom and sidewall of said trench by thermal oxidation under an operating temperature ranged from 1150 to 1300° C. and an operating time ranged from 20 to 60 minutes;
(c) removing said sacrificial oxide layer; and
(d) forming a gate oxide layer on said silicon substrate under an operating temperature ranged from 1000 to 1200° C. and on the bottom and sidewall of said trench.

2. The process according to claim 1, wherein said step (a) comprises steps of:
(a1) providing said silicon substrate;
(a2) forming a mask layer on said silicon substrate;
(a3) removing a portion of said mask layer to expose a portion of said silicon substrate;
(a4) removing said exposed portion of said silicon substrate to form said trench; and
(a5) removing remaining portion of said mask layer.

3. The process according to claim 2, wherein said mask layer is a silicon oxide layer.

4. The process according to claim 2, wherein said mask layer is a silicon nitride layer.

5. The process according to claim 2, wherein said mask layer is formed by chemical vapor deposition (CVD).

6. The process according to claim 2, wherein said step (a3) is performed by photolithography and a dry etching step.

7. The process according to claim 2, wherein said step (a4) is performed by a dry etching step.

8. The process according to claim 2, wherein said step (a5) is performed by a wet etching step.

9. The process according to claim 1, wherein said step (c) is performed by a wet etching step.

10. The process according to claim 1, wherein said step (d) is performed by thermal oxidation.

11. The process according to claim 1, wherein said sacrificial oxide layer has a thickness ranged from 1100 to 1500 Å.

12. A process for forming a gate oxide layer of a trench power MOSFET, comprising steps of:
(a) providing a silicon substrate;
(b) forming a mask layer on said silicon substrate;
(c) removing a portion of said mask layer to expose a portion of said silicon substrate;
(d) removing said exposed portion of said silicon substrate to form said trench;
(e) removing remaining portion of said mask layer;
(f) forming a sacrificial oxide layer on said silicon substrate and on the bottom and sidewall of said trench by thermal oxidation under an operating temperature ranging from 1150 to 1300° C. and an operating time ranging from 20 to 60 minutes;
(g) removing said sacrificial oxide layer; and
(h) forming a gate oxide layer on said silicon substrate under an operating temperature ranged from 1000 to 1200° C. and on the bottom and sidewall of said trench.

13. The process according to claim 12, wherein said mask layer is a silicon oxide layer.

14. The process according to claim 12, wherein said mask layer is a silicon nitride layer.

15. The process according to claim 12, wherein said sacrificial oxide layer has a thickness ranged from 1100 to 1500 Å.
